(19) United States
(12) Patent Application Publication
(10) Pub. No.: US 2007/0167011 A1
(43) Pub. Date: Jul. 19, 2007

(54) ETCHING METHOD

(75) Inventor: Munenori HIDAKA, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/566,691

(22) Filed: Dec. 5, 2006

(30) Foreign Application Priority Data
Jan. 5, 2006 (JP) 2006-000588

(51) Int. Cl. H01L 21/302

(52) U.S. Cl. 438/689

(57) ABSTRACT

In an etching method of the present invention, a first etching step for etching a silicon semiconductor region at a first etching rate with use of a first etching gas is first performed. Then, after the first etching step, a second etching step is performed in order to etch the silicon semiconductor region at a second etching rate that is lower than the first etching rate by using a second etching gas that includes carbon and fluoride, with the ratio of the fluoride in the second etching gas being higher than that of the carbon therein. Carbon is included in the second etching gas in order to chemically bind to at least either oxygen or hydrogen used in the first etching step. Therefore, it is possible to inhibit the generation of black silicon (i.e., a residue composed of silicon needles) which is caused as a result of attachment of oxygen and hydrogen on the etching surface. The resulting etched surface is smoothly formed, and black silicon is not formed thereon.

This application claims priority to Japanese Patent Application No. 2006-000588. This entire disclosure of Japanese Patent Application No. 2006-000588 is hereby incorporated herein by reference.

### BACKGROUND OF THE INVENTION

### Field of the Invention

The present invention relates to an etching method, and in particular, related to an anisotropic plasma etching method performed for a silicon semiconductor substrate.

A variety of anisotropic plasma etchings have been used for forming a trench in a semiconductor substrate. For example, Japan Patent JP-B-3527901 (especially, paragraphs 0050 to 0053 and FIG. 6) discloses steps for forming a trench in a semiconductor substrate by performing two separate plasma etching steps in order to enhance the etching ratio and yield thereof. In the first step, etching is performed so that approximately 70 to 90% of the thickness of an object is etched with use of an etching gas including SF₆ and O₂. Then, in the second step, etching is performed so that approximately 10 to 30% of the remaining thickness of the object is etched with use of an etching gas including Cl₂ and O₂. In the second step, etching gas not including fluorine is used.

Japan Patent JP-B-3267199 (especially, paragraphs 0009 and 0010, and FIG. 1) discloses that in order to prevent generation of residue such as black silicon as much as possible while a trench is formed in a semiconductor wafer by means of a dry etching processing, portions of a semiconductor region are prevented from being exposed in regions other than a trench forming region during the trench etching. Note that the black silicon indicates a residue composed of silicon needles formed on the silicon surface. This residue may be called “black silicon” because it appears in black when a wafer is observed with an optical microscope.

However, as described in Japan Patent JP-B-3527901 and Japan Patent JP-B-3267199, the conventional art cannot meet the demand to reduce the roughness of, for instance, black silicon on the surface of the bottom portion of a trench, enhance the controllability of the shape of the bottom portion of a trench, and reduce the etching processing time. Therefore, it is an object of the present invention to establish an etching method for meeting these demands.

### SUMMARY OF THE INVENTION

The etching method of the present invention comprises a first etching step for etching a silicon semiconductor region with a first etching gas at a first etching rate, and a second etching step for etching the silicon semiconductor region after the first etching step at a second etching rate that is lower than the first etching rate, with a second etching gas that includes carbon and fluoride, the ratio of the fluoride in the second etching gas being larger than that of the carbon therein.

According to the present invention, when the silicon semiconductor region is etched in the first etching step, the generation of new black silicon (i.e., residue composed of silicon needles) is prevented while black silicon previously formed on the etching surface is removed. Therefore, the silicon semiconductor region is etched in the second etching step, which functions as a finishing etching step, with the etching gas that includes carbon and fluoride, and the ratio of the fluoride is larger than that of carbon at a second etching rate that is lower than a first etching rate. Carbon included in the etching gas chemically bind to at least either oxygen or hydrogen used in the first etching step. Therefore, it is possible to inhibit generation of black silicon which is caused as a result of attachment of oxygen and hydrogen on the etching surface. The resulting etched surface is smoothly formed, and black silicon is not formed thereon.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a partial vertical cross-sectional view of a semiconductor substrate in one step of a selective anisotropic plasma etching method in accordance with a first embodiment of the present invention;

FIG. 2 is a partial vertical cross-sectional view of the semiconductor substrate in one step of the selective anisotropic plasma etching method in accordance with the first embodiment of the present invention;

FIG. 3 is a partial vertical cross-sectional view of the semiconductor substrate in one step of the selective anisotropic plasma etching method in accordance with the first embodiment of the present invention;

FIG. 4 is a partial vertical cross-sectional view of the semiconductor substrate in one step of the selective anisotropic plasma etching method in accordance with the first embodiment of the present invention;

FIG. 5 is a partial vertical cross-sectional view of the semiconductor substrate in one step of the selective anisotropic plasma etching method in accordance with the first embodiment of the present invention;

FIG. 6 is a flow chart explaining steps of the selective anisotropic plasma etching method in accordance with the first embodiment of the present invention;

FIG. 7 is an electrophotograph showing a bottom portion of a trench formed by etching a silicon substrate under conditions in which an etching gas comprised of a SF₆ gas and an O₂ gas is used and the etching rate is set to be 3.2 μm min;

FIG. 8 is an electrophotograph showing a bottom portion of a trench formed by etching a silicon substrate under conditions in which an etching gas comprised of a SF₆ gas and a CF₄ gas is used and the etching rate is set to be 0.375 μm/min;

FIG. 9 is a partial vertical cross sectional view showing the vertical cross sectional shape of a trench formed as a result of a finishing etching step under conditions in which the ratio of the gas flow rate of CF₄ to that of SF₄ is set to be low;

FIG. 10 is a partial vertical cross-sectional view explaining the relaxation of stress applied to a silicon substrate when a thermal oxide film is formed on a sidewall of the trench and a bottom portion shown in FIG. 9;

FIG. 11 is a partial vertical cross sectional view showing the vertical cross sectional shape of a trench formed as a result of an finishing etching step under conditions in which the ratio of the gas flow rate of CF₄ to that of SF₆ is set to be low; and

FIG. 12 is a partial vertical cross-sectional view explaining an increase in stress applied to the silicon substrate when a thermal oxide film is formed on a bottom portion of a trench shown in FIG. 11 and a laminated structure comprised of a thermal oxide film and polysilicon is formed on a sidewall.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

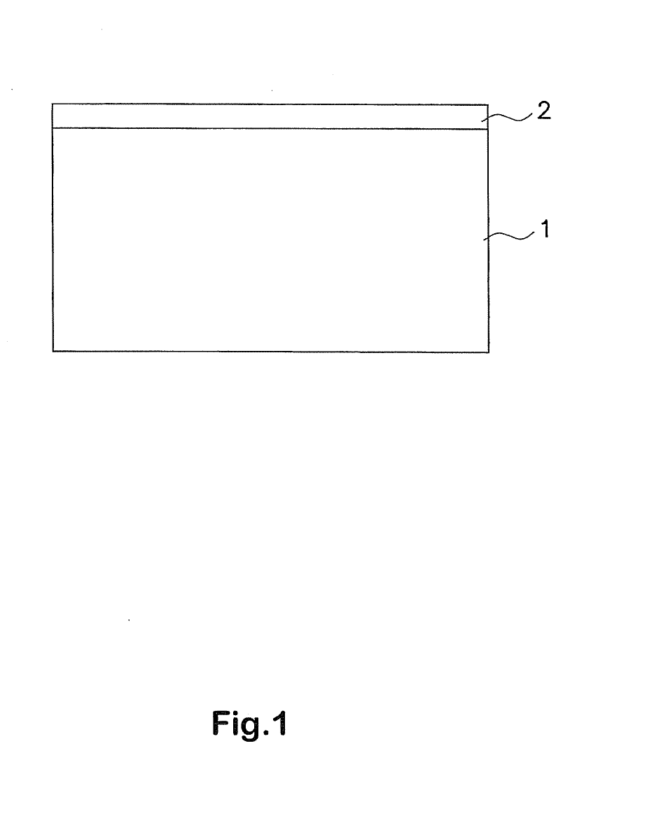

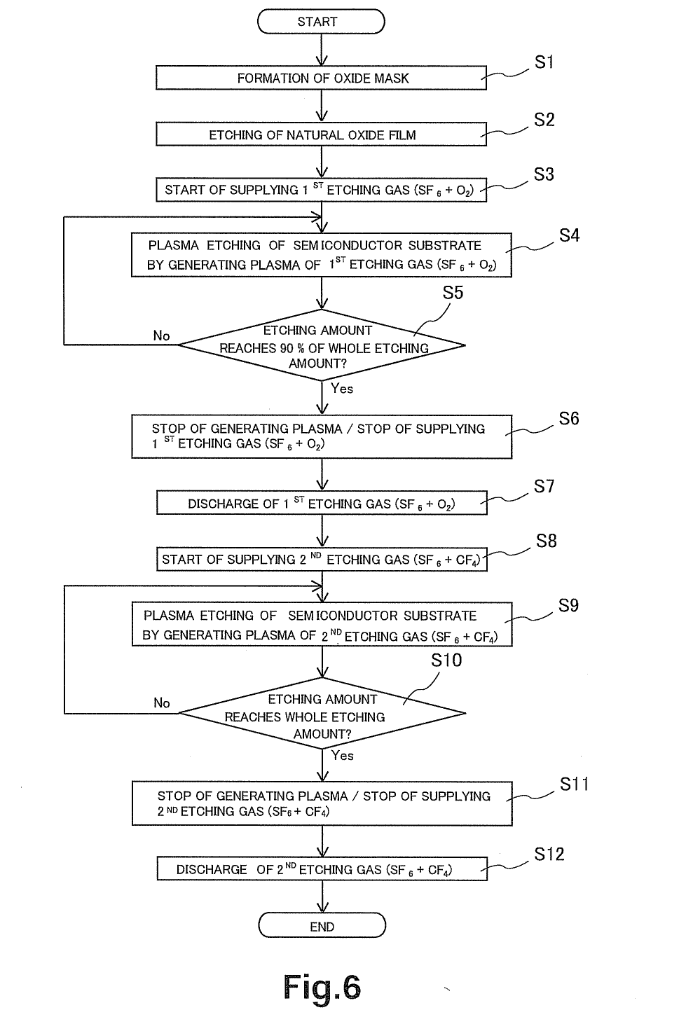

The first embodiment of the present invention provides a selective anisotropic plasma etching method for forming a trench in a semiconductor substrate. FIGS. 1 to 5 are partial vertical cross-sectional views of a semiconductor substrate in each of the steps performed in a selective anisotropic plasma etching method in accordance with the first embodiment of the present invention. FIG. 6 is a flow chart explaining steps performed in the selective anisotropic plasma etching method in accordance with the first embodiment of the present invention.

As shown in FIG. 1, a silicon substrate 1 is prepared. A natural oxide film 2 is formed on the surface of the silicon substrate 1.

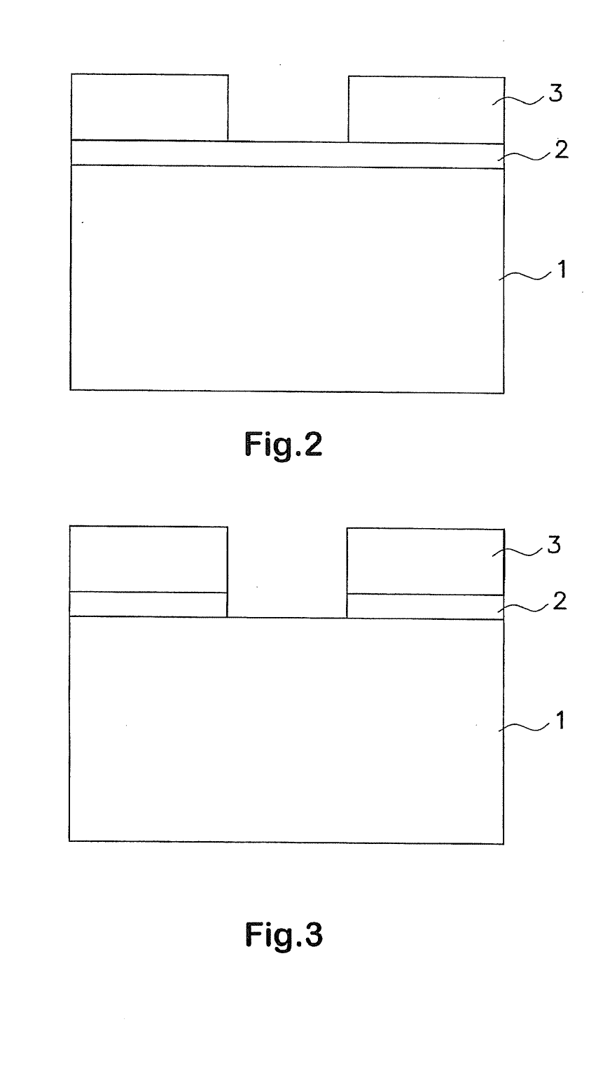

As shown in FIG. 2, an etching mask 3 is formed in a heretofore known method. This step corresponds to Step S1 shown in FIG. 6. The etching mask 3 can be comprised of oxide silicon, for instance. However, it is not necessarily limited to this configuration. The etching mask 3 can be comprised of any type of heretofore known materials functioning as an etching mask.

As shown in FIG. 3, the natural oxide film 2 is removed by means of etching with use of the etching mask 3. This step corresponds to Step S2 shown in FIG. 6. Here, the etching amount is set to be 10 nm or greater, which is converted based on the etching amount with respect to the silicon substrate 1. The etching selectivity, that is, the ratio of the etching rate of SiO₂ to that of Si, is set to be 10 or less.

In Step S3 shown in FIG. 6, a supply of a SF₆ gas and an O₂ gas into the interior of an etching chamber is started for the purpose of starting a first trench etching step for forming an objective trench in the silicon substrate 1. The mixture of the SF₆ gas and the O₂ gas is used as an etching gas.

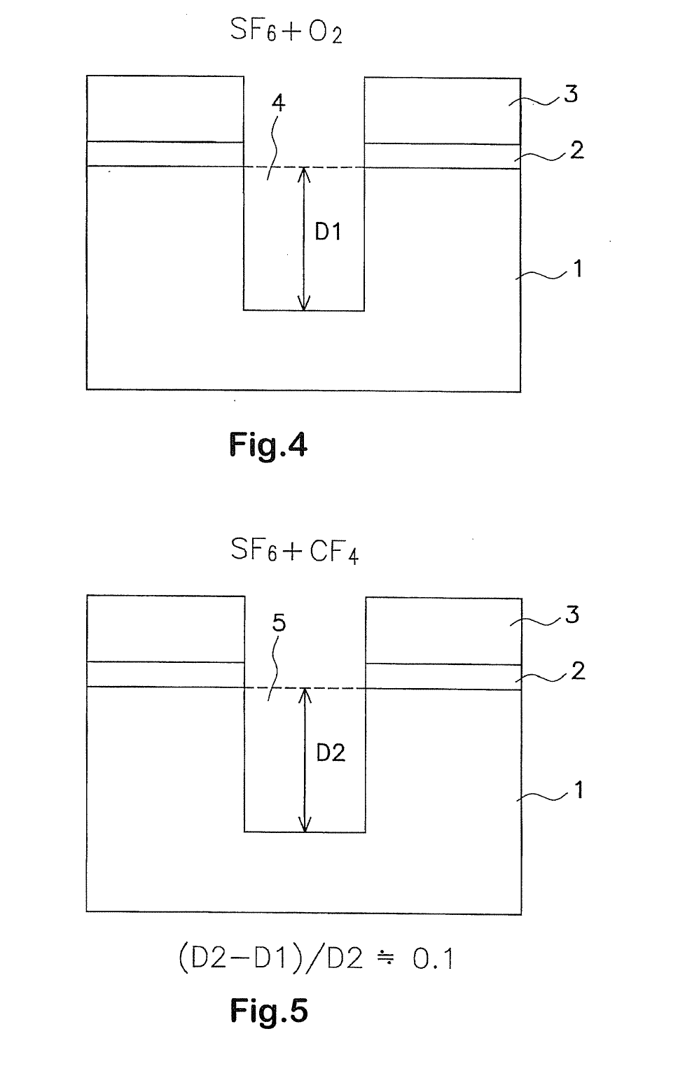

As shown in FIG. 4, the first trench etching step is performed by generating a plasma of the mixture of the SF₆ gas and the O₂ gas. This step corresponds to Step S4 shown in FIG. 6. The following are the conditions for generating a plasma. The mixture of the SF₆ gas and the O₂ gas (i.e., SF₆/O₂ mixed gas) is used as a first etching gas. The gas flow rate of the SF₆ gas is set to be 55 mL/min. The gas flow rate of the O₂ gas is set to be 15 mL/min. The ratio of the gas flow rate of SF₆ gas and that of O₂ gas is 11:3. The gas pressure is set to be 3 Pa. The microwave power is set to be 600 W. The high frequency power is set to be 15 W. The sample temperature is set to be −40 degrees Celsius. The first trench etching step with respect to the silicon substrate 1 is started with use of the etching mask 3 under these conditions. The first trench etching step is the main etching step, and the silicon substrate 1 is etched at a reasonably achievable highest etching rate.

In Step S5 shown in FIG. 6, the first trench etching step is continued until such time that a predetermined necessary amount, that is, 90% of the whole etching amount, is etched.

In Step S6 shown in FIG. 6, the generation of plasma is stopped and the supply of the first etching gas (i.e., SF₆/O₂ mixed gas) is also stopped when the etching amount in the first trench etching step corresponds to 90% of the whole etching amount. As shown in FIG. 4, a trench 4 with a depth D1 is formed in the silicon substrate 1 at this point.

In Step S7 shown in FIG. 6, the first etching gas (i.e., SF₆/O₂ mixed gas) is discharged from the interior of the etching chamber.

In Step S8 shown in FIG. 6, a supply of a SF₆ gas and a CF₄ gas into the interior of the etching chamber is started for the purpose of starting a second trench etching step that is a final etching step for forming an objective trench in the silicon substrate 1. The mixture of the SF₆ gas and the CF₄ gas (i.e., SF₆/CF₄ mixed gas) is used as a second etching gas.

As shown in FIG. 5, the second trench etching step is performed by generating a plasma of the mixture of the SF₆ gas and the CF₄ gas (i.e., SF₆/CF₄ mixed gas). This step corresponds to Step S9 shown in FIG. 6. The following are the conditions for generating a plasma. The mixture of the SF₆ gas and the CF₄ gas is used as an etching gas. The gas flow rate of the SF₆ gas is set to be 6 mL/min. The gas flow rate of the CF₄ gas is set to be 80 mL/min. The ratio of the gas flow rate of the SF₆ gas and that of the CF₄ gas is 3:40. The gas pressure is set to be 0.8 Pa. The microwave power is set to be 600 W. The high frequency power is set to be 75 W. The sample temperature is set to be −40 degrees Celsius. Finishing of the trench etching step with respect to the silicon substrate 1 is performed with reuse of the etching mask 3 under these conditions. The ratio of the gas flow rate of the SF₆ gas and that of the CF₄ gas is set to be 3:40 so that the etching rate in the second trench etching step is one-tenth of the etching rate in the above described first trench etching step.

In Step S10 shown in FIG. 6, the second trench etching step is continued until such time that a predetermined necessary amount, that is, 10% of the whole etching amount, is etched. In other words, most of the trench forming steps are completed by the above described first trench etching step, and the finishing of the trench forming steps is performed by the second trench etching step. In the above described first etching step, the etching gas including oxygen (O₂) or an oxide is used as the first etching gas in order to perform etching with a sufficiently high etching rate in the shortest possible time, that is, in order to make the etching rate sufficiently high. Because of this, oxygen (O₂) or an oxide attaches to portions of the etching surface that is exposed to the first etching gas in a plasma state. As a result, the etching rate of the portions of the etching surface to which oxygen (O₂) or an oxide attaches will be lower than that of the etching surface through which silicon is exposed. Even if the portions to which oxygen (O₂) or an oxide attaches are etched as etching proceeds, the etching surface is exposed to the first etching gas during the first trench etching step. Therefore, oxygen (O₂) or an oxide newly attaches thereto. As a result, black silicon is formed on the surface of the bottom portion of the trench 4 formed in the above described first trench etching step.

Accordingly, the second trench etching step is performed as a finishing of the trench forming steps. The trench 4 with the depth D1 is formed through the above described first trench etching step. The depth D1 corresponds to approximately 90% of an ultimately desired depth D2. Therefore, the remaining 10% of the depth D2 may be further etched in the second trench etching step. Accordingly, even if the etching rate is low, it is important in the second etching step to remove oxygen (O₂) or an oxide that attaches to the surface of the bottom portion of the trench 4 in the first trench etching step and to prevent attachment of oxygen (O₂) or an oxide that will be a new obstacle for etching thereto. In consideration of this point, an etching gas including carbon (C), which is an element that easily forms a chemical bond with oxygen (O₂) or an oxide, is selected as the second etching gas used in the second trench etching step. Specifically, the second trench etching step is performed with use of the above described mixture of the SF₆ gas and the CF₄ under the above described conditions. A sufficient amount of carbon (C) is included in the second etching gas. Therefore, if the second trench etching step is started, oxygen (O₂) or an oxide that attaches to the surface of the bottom portion of the trench 4 in the above described first trench etching step will be removed, and black silicon formed on the surface of the bottom portion of the trench 4 will be etched. In addition, a finishing etching step is performed without attachment of oxygen (O₂) or an oxide that will be a new obstacle for etching. The etching rate in the second trench etching step in which the mixture of the SF₆ gas and the CF₄ gas is used is one-tenth of the etching rate of the first trench etching step in which the mixture of the SF₆ gas and the O₂ gas is used. However, the amount to be etched is approximately 10% of the ultimately desired depth D2. Therefore, the impact on the average of the etching rate is small when it is considered in all of the etching steps. Thus, the problem of etching rate reduction will not be caused. Furthermore, the second trench etching step with the low etching rate is performed in the finishing phase. Accordingly, it will be easy to adjust the ultimately desired depth D2 of the trench 5 with high accuracy.

In Step S11 shown in FIG. 6, generation of plasma is stopped and supply of the second etching gas (i.e., SF₆/CF₄ mixed gas) is also stopped when the etching amount in the second trench etching step corresponds to 10% of the whole etching amount. The objective trench 5 with the depth D2 is formed in the silicon substrate 1. The objective trench 5 has the ultimately desired depth D2, and the surface of the bottom portion has little black silicon attached thereto.

In Step S12 shown in FIG. 6, the etching steps are completed by discharging the second etching gas (i.e., SF₆/CF₄ mixed gas) from the interior of the etching chamber.

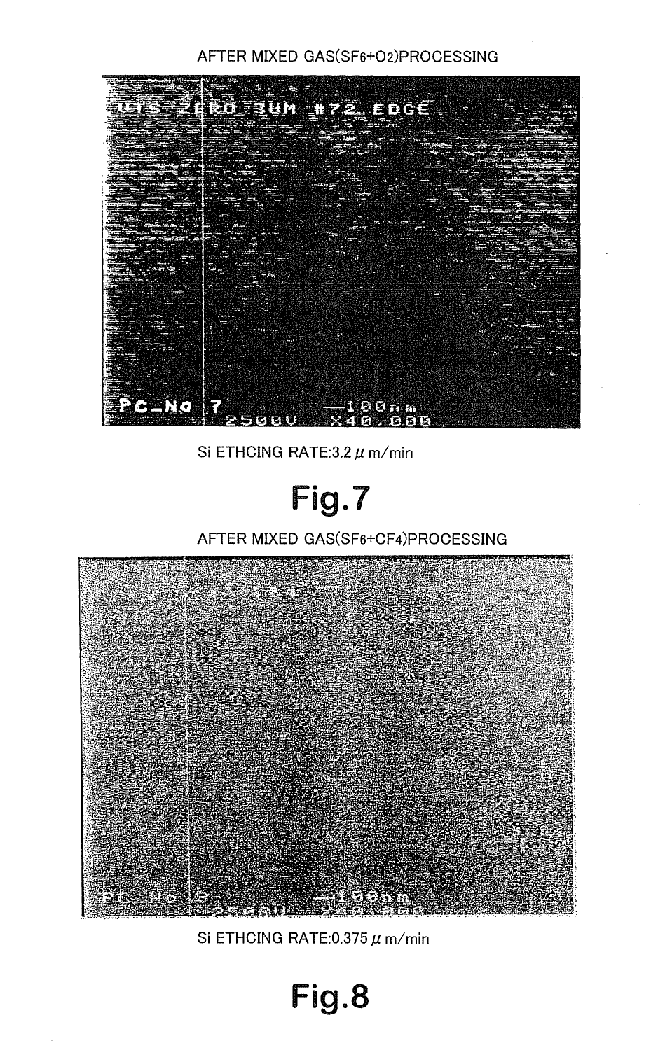

FIG. 7 is an electrophotograph showing the condition of the surface of the bottom portion of the trench 4 formed by etching the silicon substrate under conditions in which the first etching gas (i.e., SF₆/O₂ mixed gas) is used and the etching rate is set to be 3.2 μm/min. FIG. 8 is an electrophotograph showing the condition of the surface of the bottom portion of the trench 5 formed by etching the silicon substrate under conditions in which the second etching gas (i.e., SF₆/CF₄ mixed gas) is used and the etching rate is set to be 0.375 μm/min. Here, as shown in FIG. 7, when the first etching gas (i.e., SF₆/O₂ mixed gas) is used, the roughness of the surface of the bottom portion of the trench 4 can be identified. This roughness shows that black silicon exists on the surface of the bottom portion of the trench 4. As described above, this black silicon is generated by attachment of oxygen (O₂) or an oxide to the etching surface. Here, the attachment of oxygen (O₂) or an oxide means oxide film deposition. In other words, the reason for attachment of oxygen (O₂) or an oxide is that the above described first etching gas includes oxygen (O₂). Furthermore, this attachment will be a reason for variations in the etching rate. This variation in the etching rate is a reason for the generation of black silicon and the roughness of the surface of the bottom portion of the trench 4. That is to say, inclusion of oxygen (O₂) in the above described first etching gas is a reason for the generation of black silicon and the roughness of the surface of the bottom portion of the trench 4. Note that the ease in which black silicon is generated depends on the pattern ratio of the etching mask. Specifically, black silicon is easily generated if the pattern ratio of the etching mask is low and the area to be etched is large.

On the other hand, as shown in FIG. 8, when the above described etching gas (i.e., SF₆/CF₄ mixed gas) is used, the smoothness of the surface of the bottom portion of the trench 4 without roughness can be identified. This smoothness shows that black silicon does not exist on the surface of the bottom portion of the trench 5. As described above, black silicon is generated by attachment of oxygen (O₂) or an oxide on the etching surface. That black silicon does not exist on the surface of the bottom portion of the trench 5 means that oxygen (O₂) or an oxide having existed on the surface of the bottom portion of the trench 5 is removed, and at the same time as this, oxygen (O₂) or an oxide does not newly attach to the surface of the bottom portion of the trench 5. The above described second etching gas (i.e., SF₆/CF₄ mixed gas) includes carbon (C) or carbide. This carbon (C) chemically reacts with the remaining oxygen (O₂) or an oxide, and thus oxygen (O₂) or an oxide is prevented from newly attaching to the surface of the bottom portion of the trench 5, and the oxide film deposition attached to the surface of the bottom portion of the trench 5 is removed by means of the original etching effect. Because of this, the etching surface is comprised of silicon without oxygen (O₂) or an oxide. Furthermore, black silicon that was formed in the previous etching step is removed by etching with use of the above described second etching gas (i.e., SF₆/CF₄ mixed gas). As a result, the ultimately obtained trench 5 has a smooth surface on the bottom portion thereof without black silicon, as shown in FIG. 8.

Based on the above, following conclusions can be made. That is, FIG. 7 shows that the trench formed in the first etching step with use of the first etching gas (i.e., SF₆/O₂ mixed gas) including oxygen (O₂) or an oxide has a rough surface on the bottom portion thereof on which black silicon exists. On the other hand, FIG. 8 shows that the trench formed in the second etching step with use of the second etching gas (i.e., SF₆/CF₄ mixed gas) including carbon (C) or carbide has a smooth surface on the bottom portion thereof on which black silicon does not exist.

It is preferable to decide the ratio of the etching amount by the second etching step with use of the second etching gas (i.e., SF₆/CF₄ mixed gas) to the etching amount by the first etching step with use of the first etching gas (i.e., SF₆/O₂ mixed gas) by considering the entire etching processing time and the removal of black silicon formed on the surface of the bottom portion of the trench in the first etching step. The etching rate of the second etching step is lower than that of the first etching step. Therefore, it is better to reduce the etching amount in the second etching step as much as possible in order to reduce the entire etching processing time as much as possible. On the other hand, black silicon can be removed in the second etching step. Therefore, when the second etching step is performed so that the etching amount can correspond to the minimal etching amount required for removing black silicon, it is possible to shorten the entire etching processing time as much as possible and to remove black silicon.

As described above, the ease with which black silicon is generated depends on the pattern ratio of the etching mask. Specifically, black silicon is easily generated if the pattern ratio of the etching mask is low and the area to be etched is large. The etching amount in the second etching step, which is minimally required if the pattern ratio of the etching mask is low and much black silicon is generated, is larger than the etching amount in the second etching step, which is minimally required if the pattern ratio of the etching mask is high and less black silicon is generated. Therefore, the minimally required etching amount in the second etching step depends on the amount of black silicon, and indirectly depends on the pattern ratio of the etching mask.

Furthermore, when the etching mask is comprised of a silicon oxide film, the silicon oxide film is exposed to a plasma gas during the etching step. Accordingly, oxygen (O₂) or an oxide is provided from the silicon oxide film to the etching surface, that is, the bottom portion of the trench. Therefore, in addition to the first etching gas (i.e., SF₆/O₂ mixed gas), the etching mask comprised of the silicon oxide film will be a supply source of oxygen (O₂) or an oxide. Therefore, when the etching mask is comprised of the silicon oxide film, a large amount of black silicon is generated compared to when the etching mask is comprised of a material that does not include oxygen. Thus, the etching amount must be increased in the second etching step. That is to say, it is preferable to consider whether or not the etching mask is comprised of a material including silicon when deciding the etching amount in the second etching step.

Therefore, it is not necessary to limit the configuration of the etching step to the above described example in which the etching amount in the first etching step is set to be 90% of the whole etching amount (i.e., objective etching amount) and the etching amount in the second etching step is set to be 10% of the whole etching amount. It is preferable to set the etching amount in the second etching step to be 3 to 20% of the whole etching amount in consideration of the removal of black silicon and the reduction of the entire etching processing time. If the etching amount in the second etching step is set to be less than 3% of the whole etching amount, a sufficiently significant effect of reducing the entire etching processing time can be expected, but the removal of black silicon cannot be expected. On the other hand, if the etching amount in the second etching step is set to be more than 20% of the whole etching amount, a sufficiently significant effect of removing black silicon can be expected, but a reduction of the entire etching processing time cannot be expected. It is preferable to set the ratio of the etching amount in the second etching step to the sum of the etching amounts in the first and second etching steps to be within the range of 3 to 20% for the purpose of achieving both a sufficiently significant effect of removing black silicon and a reduction of the entire etching processing time.

According to the present invention, the trench 5 having a surface on the bottom portion thereof on which black silicon does not exist can be obtained by finishing the etching steps in the second etching step with the use of the second etching gas including carbon (C) or a carbide that chemically binds with an oxygen (O₂) or an oxide. As described above, the amount of carbon (C) included in the second etching gas (i.e., SF₆/CF₄ mixed gas) has an impact on the removal efficiency of black silicon. In addition to this, this has an impact on the vertical cross-sectional shape of the trench. The amount of carbon (C) included in the second etching gas (i.e., SF₆/CF₄ mixed gas), that is, the interrelationship between the ratio of the gas flow rate of the CF₄ gas to that of the SF₆ gas and the vertical cross-sectional shape of the trench will be hereinafter explained.

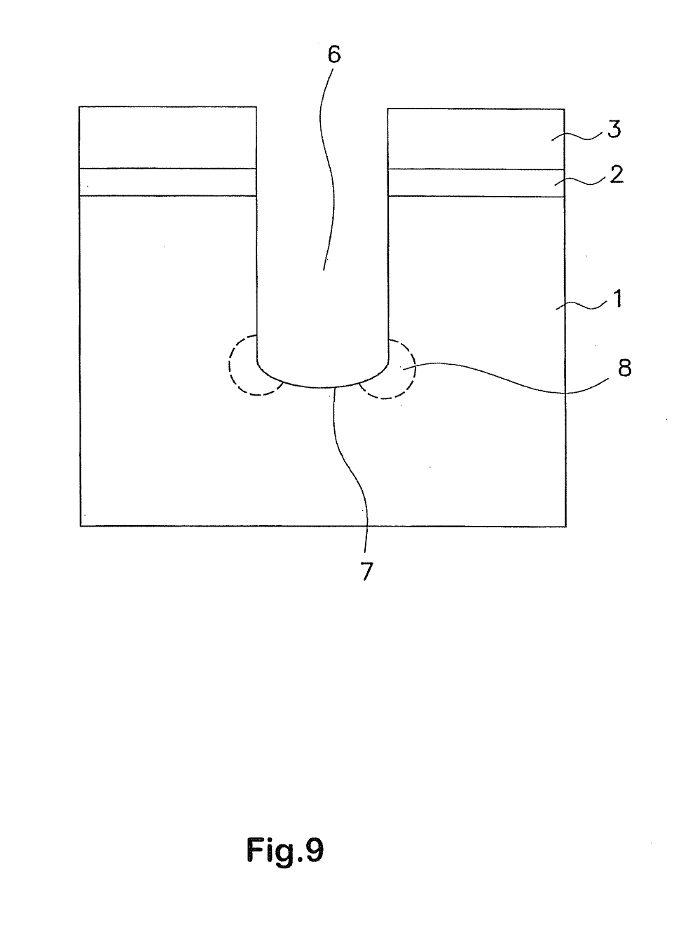

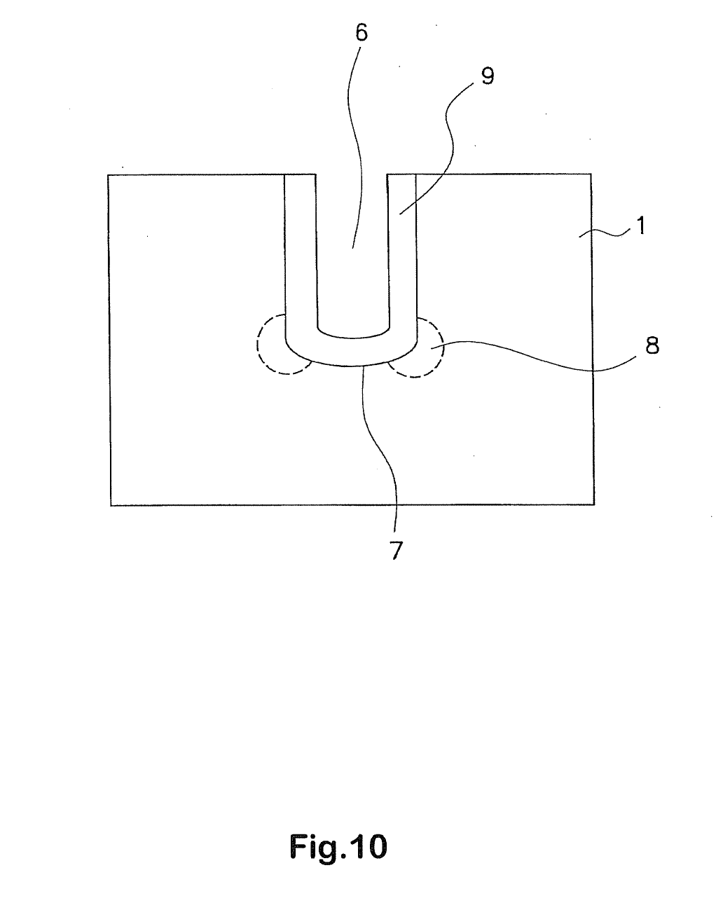

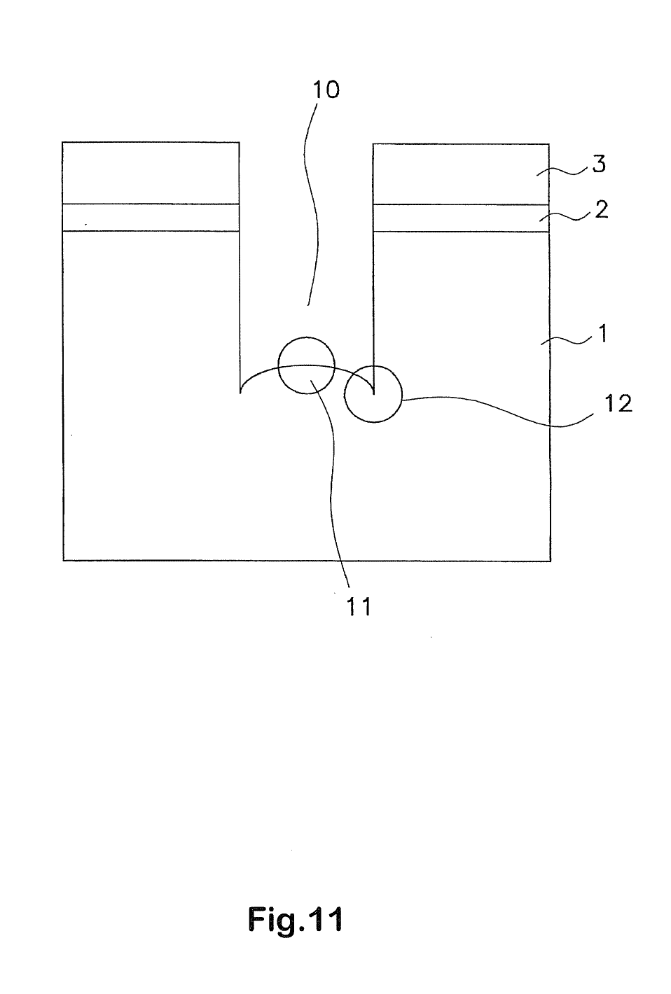

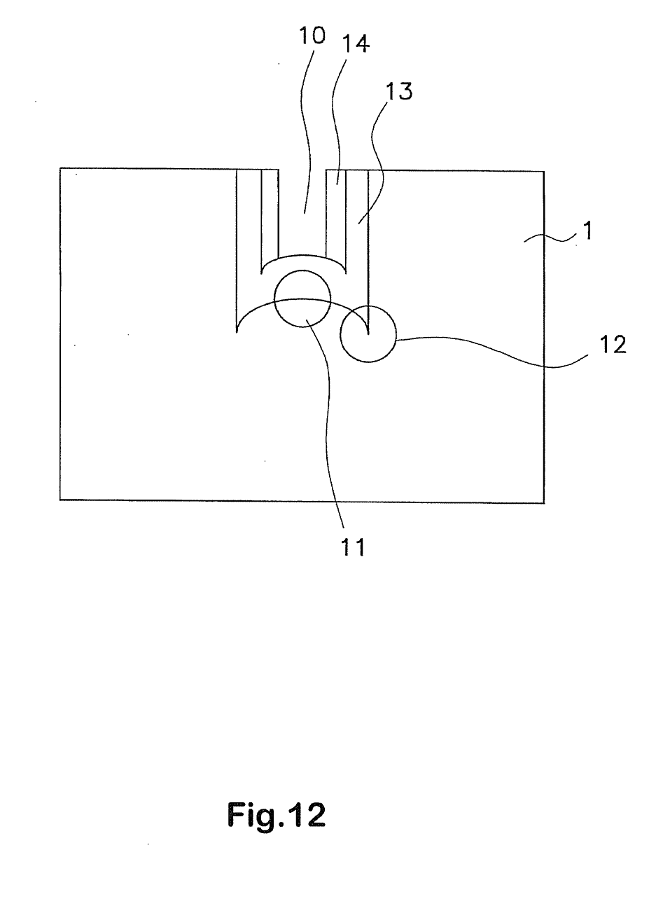

FIG. 9 is a partial vertical cross sectional view showing the vertical cross sectional shape of a trench formed as a result of an finishing etching step under conditions in which the gas flow ratio of CF₄ gas to SF₆ gas is set to be low. FIG. 10 is a partial vertical cross-sectional view explaining the relaxation of stress applied to a silicon substrate when a thermal oxide film is formed on a sidewall of the trench and a bottom surface shown in FIG. 9. FIG. 11 is a partial vertical cross sectional view showing the vertical cross sectional shape of a trench formed as a result of a finishing etching step under conditions in which the gas flow ratio of CF₄ gas to SF₆ gas is set to be high. FIG. 12 is a partial vertical cross-sectional view explaining an increase in stress applied to the silicon substrate when a thermal oxide film is formed on the bottom portion of a trench shown in FIG. 11 and a laminated structure comprised of a thermal oxide film and polysilicon is formed on a sidewall.

The trench shown in FIG. 9 is formed by the combination of the above described first and second etching steps. Here, when the above described second etching step is performed, the bottom portion 7 of the formed trench 6 is formed so that depth of its center portion is deeply formed and that of its other portions is formed to be gradually shallow toward a sidewall of the trench 6 by setting the gas flow ratio of CF₄ gas to SF₆ gas to be lower than the above described ratio. Furthermore, a boundary portion 8 that is located between the bottom portion of the trench 6 and the sidewall thereof has a round shape. That is, reducing the amount of carbon (C) or a carbide included in the etching gas used for the second etching step makes it possible to obtain the trench 6 that comprises the bottom portion 7 in which the depth of its center portion is deeply formed and that of its other portions is formed to be gradually shallow toward the sidewall of the trench 6 as shown in FIG. 9, and a boundary portion 8 that is located between the bottom portion 7 and the sidewall and has a round shape. Then, as shown in FIG. 10, an insulation film 9 is formed to cover the bottom portion 7, the boundary portion 8, and the sidewall of the trench 6. The insulation film 9 may be a thermal oxide film or a TEOS-CVD film. When the insulation film 9 is formed to cover the bottom portion 7, the boundary portion 8, and the sidewall of the trench 6, stress is applied on the silicon of the boundary portion 8 between the bottom portion 7 and the sidewall portion of the trench 6. However, the round shape of the boundary portion 8 between the bottom portion 7 and the sidewall relaxes this stress.

The trench shown in FIG. 11 is formed by the combination of the above described first and second etching steps. Here, when the above described second etching step is performed, a bottom portion 11 of the formed trench 10 is formed so that the depth of its center portion is shallowly formed and that of its other portions is formed to be gradually deeper toward the sidewall of the trench 10 by setting the gas flow ratio of CF₄ gas to SF₆ gas to be higher than the above described ratio. Furthermore, a boundary portion 12 that is located between the bottom portion 11 and the sidewall has an acute-angled shape. That is, increasing the amount of carbon (C) or a carbide included in the etching gas used for the second etching step makes it possible to obtain the trench 10 shown in FIG. 11 that comprises the bottom portion 11 in which the depth of its center portion is shallowly formed and that of its other portions is formed to be gradually deeper toward the sidewall of the trench 10, and a boundary portion 12 that is located between the bottom portion 11 and the sidewall and has an acute-angled shape. Then, as shown in FIG. 12, an insulation film 13 is formed to cover the bottom portion 11, the boundary portion 12, and the sidewall of the trench 10. The insulation film 13 may be a thermal oxide film or a TEOS-CVD film. When the insulation film 13 is formed to cover the bottom portion 11, the boundary portion 12, and the sidewall of the trench 10, stress that is applied to the silicon of the boundary portion 12 between the bottom portion 11 and the sidewall portion of the trench 10 will be increased. The acute-angled shape of the boundary portion 12 between the bottom portion 11 and the sidewall increases stress that is applied to the silicon in the boundary portion 12. Then, a conductive film 14 can be selectively formed only along the sidewall of the trench 10. Specifically, the conductive film 14 is formed on the entire exposed surface of the insulation film 13 and the silicon substrate 1, and then the conductive film 14 is etched by means of isotropic etching. Thus, portions of the conductive film 14 formed to be disposed on the bottom portion of the trench 10 and immediately on the silicon substrate 1 can be removed. The conductive film 14 may be a polysilicon film, for instance. The shape of the bottom portion 11, that is, the shape that the depth of its center portion is formed to be shallow and that of its other portions is formed to be gradually deeper toward the sidewall of the trench 10, makes it possible to leave only the portion of the conductive film 14 that is disposed along the sidewall of the trench 10 by means of isotropic etching. When the second etching step is performed by increasing the amount of carbon (C) and carbide, stress applied to silicon of the boundary portion 12 between the bottom portion 11 and the sidewall of the trench 10 will be increased. However, it will be easy to selectively form the conductive film 14 only on the sidewall of the trench 10. In other words, it will be possible to separate the bottom portion 11 and the sidewall of the trench 10 from each other.

Therefore, it will be possible to remove black silicon and to adjust the depth of the trench with high accuracy by adjusting the etching amount in the second etching step that is performed as a finishing etching step with use of the second etching gas including carbon (C) or a carbide. In addition, it will be possible to adjust the efficiency of removing black silicon, and the ultimately obtained trench shape, by adjusting the amount of carbon included in the second etching gas.

Note that it is possible to adjust the trench shape by adjusting the processing time required for the second etching step, the pressure of the second etching gas, and the temperature of the silicon substrate 1, in addition to adjusting the amount of carbon (C) or a carbide included in the etching gas used in the above described second etching step.

The above described first etching step is a main step of etching, and it is mainly required that the etching rate therein is set to be high. The SF₆/O₂ mixed gas is used as the above described first etching gas. However, the first etching gas is not limited to this composition. For example, a Cl₂/O₂ mixed gas, a Cl₂/HBr mixed gas, or a CL₂/HBr/O₂ mixed gas may be used. If at least either oxygen (O₂) or hydrogen (H) is included in the first etching gas, these elements or compounds attach to the etching surface, and variation of the etching rate will be caused. As a result, black silicon is formed on the bottom portion of the trench.

Accordingly, it will be possible to ultimately obtain a trench that has a smooth bottom portion on which black silicon does not exist by removing black silicon as a result of performing the second etching step functioning as a finishing etching step with use of the second etching gas including carbon (C) or a carbide. In addition, as described above, the etching rate in the second etching step is low. Therefore, the ability to control the depth of the ultimately obtained trench will be enhanced. Furthermore, as described above, it will be possible to adjust the shape of the ultimately obtained trench by adjusting the amount of carbon (C) included in the second etching gas.

When the removal of black silicon and the tolerance level of the trench shape are taken into consideration, the second etching gas must include carbon (C) and fluoride (F) such that the ratio of fluoride is larger than that of carbon. In addition, it is preferable that the second etching gas does not include any oxygen and hydrogen, which will be a factor in causing variation of the etching rate. When the amount of fluoride (F) included in the second etching gas increases, the anisotropy of etching will be reduced, and thus the ultimately obtained trench will lose shape. On the other hand, if the amount of carbon (C) included in the second etching gas increases, the etching rate will be reduced. Therefore, when the trench shape and the etching rate are taken into consideration, it is preferable to set the weight ratio of fluoride to carbon to be in a range of 90:1 to 6:1. If the weight ratio of fluoride is higher then this range, the ultimately obtained trench will greatly lose shape. Therefore, this is not preferable. Furthermore, it is more preferable to set the weight ratio of fluoride to carbon to be in a range of 40:1 to 6:1. If the weight ratio of fluoride to carbon is in this range, the trench will not substantially lose shape. Therefore, this is preferable.

As described above, the first etching gas may be discharged from the interior of the etching chamber after the first etching step, and then the second etching step may be started by supplying the second etching gas to the interior of the etching chamber. However, even if the first etching gas is discharged from the interior of the etching chamber, oxygen or hydrogen will remain in the interior of the chamber unless the interior of the etching chamber is in the vacuum state. Therefore, it is necessary to prevent attachment of oxygen or hydrogen to the etching surface in a finishing etching step by generating carbon dioxide or carbon hydrogen by means of a chemical reaction between the remaining oxygen or hydrogen and carbon. Therefore, even if the second etching gas is introduced into the interior of the etching chamber after the first etching gas is discharged from the interior of the etching chamber, it is necessary for the second etching gas to include fluoride for etching silicon, and carbon (C) or a carbide for chemically binding with the remaining oxygen or hydrogen.

In addition, it is also possible to replace the first etching gas including SF₆ and O₂ with the second etching gas including SF₆ and CF₄ by stopping the supply of O₂ and starting the supply of CF₄ while the supply of SF₆ is maintained after the first etching step. Here, a step for discharging the first etching gas from the interior of the etching chamber is not included. Therefore, oxygen remains in the interior of the etching chamber. Therefore, it is necessary to prevent the attachment of oxygen to the etching surface in the finishing etching step by generating carbon dioxide by means of a chemical reaction between the remaining oxygen and carbon. Therefore, even if the second etching gas is introduced into the interior of the etching chamber after the supply of O₂ is stopped, it is necessary for the second etching gas to include fluoride for etching silicon, and carbon (C) or carbide for chemically binding with the remaining oxygen.

In addition, it is possible to use a Cl₂/O₂ mixed gas, a Cl₂/HBr mixed gas, or a Cl₂/HBr/O₂ mixed gas as the first etching gas. However, Cl₂ gas is used herein. Therefore, the Cl₂ gas that attached to the silicon surface will easily induce corrosion of the transport portion of a facility when the processed silicon wafer is transported to the transport portion of the facility. However, the second etching gas includes a SF₆/CF₄ mixed gas, and thus substitution of a fluorine gas with the CL₂ gas will be possible in the interior of the etching chamber and on the surface of the silicon wafer in the last step of the processing. Thus, it will be possible to inhibit corrosion of the transport portion of the facility caused by the transported silicon wafer. In other words, it is possible to perform the second etching step by stopping the supply of the first etching gas and starting supply of the second etching gas (i.e., SF₆/CF₄ mixed gas). In addition, it is possible to simultaneously perform a cleaning process by causing substitution reactions between Cl₂, and SF₆ and CF₄.

Furthermore, a NF₄/CF₄ mixed gas or a SF₆/NF₄/CF₄ mixed gas may be used instead of using the second etching gas (i.e., SF₆/CF₄ mixed gas). In other words, the second etching gas can include a CF₄ gas and at least either of a SF₆ gas and a NF₄ gas.

In the above described embodiment, the trench is formed by selective anisotropic plasma etching with respect to the silicon semiconductor substrate. However, it is not necessary to limit application of etching to formation of the trench. The present invention can be applied to a method of etching the whole surface of the silicon substrate by performing anisotropic plasma etching, without using a hole with a bottom portion or a mask. In other words, it is not necessary to particularly limit the object to be formed by etching.

Note that it is also possible to form a multistage trench by repeating the combination of the above described first etching step and the second etching step performed after the first etching step a plurality of times.

In addition, the silicon substrate is an object to be etched in the present embodiment. However, it is not necessary to limit the object to be etched to the bulk region of silicon. For example, etching can be applied to a silicon substrate having an EPI layer, a silicon-on-insulator (SOI) substrate, a silicon-on-sapphire (SOS) substrate, or a silicon-on-quartz (SOQ) substrate. Furthermore, when a region comprised of a silicon semiconductor material for which silicon is used as its basic ingredient, the above described black silicon is generated. Therefore, applying the present invention to this case is of great significance.

### General Interpretation of Terms

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applied to words having similar meanings such as the terms, “including,” “having,” and their derivatives. Also, the term “part,” “section,” “portion,” “member,” or “element” when used in the singular can have the dual meaning of a single part or a plurality of parts. Finally, terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. An etching method, comprising:
a first etching step of etching a silicon semiconductor region with a first etching gas at a first etching rate; and
a second etching step of etching the silicon semiconductor region after the first etching step with a second etching gas comprising carbon and fluoride at a second etching rate that is lower than the first etching rate, the percentage of the fluoride in the second etching gas being larger than that of the carbon therein.

2. The etching method according to claim 1, wherein the first etching gas comprises at least either hydrogen or oxygen.

3. The etching method according to claim 1, wherein the second etching gas is comprised of CF₄ and at least either SF₆ or NF₄.

4. The etching method according to claim 1, wherein the second etching gas is set so that the weight ratio of fluoride to carbon is in a range of 90:1 to 6:1.

5. The etching method according to claim 1, wherein the second etching gas is set so that the weight ratio of fluoride to carbon is in a range of 40:1 to 6:1.

6. The etching method according to claim 1, wherein anisotropic etching is performed in the first and second etching steps, and the percentage of a second etching amount performed in the second etching step to the sum of a first etching amount in the first etching step and the second etching amount is in a range of 3 to 20%.

7. The etching method according to claim 1, further comprising an etching mask forming step of selectively forming an etching mask comprised of an oxide on the silicon semiconductor region before the first etching step.

8. The etching method according to claim 1, wherein the second etching step is started by discharging the first etching gas from the interior of an etching chamber after the first etching step, and then providing the second etching gas in the interior of the etching chamber.

9. The etching method according to claim 1, wherein the first etching gas comprises SF₆ and O₂.

10. The etching method according to claim 9, wherein the first etching gas comprising SF₆ and O₂ is changed to the second etching gas comprising SF₆ and CF₄ after the first etching step by stopping a supply of O₂ and starting a supply of CF₄ while a supply of SF₆ is maintained, until the second etching step is started.

11. The etching method according to claim 1, wherein the first etching gas comprises Cl₂ and O₂.

12. The etching method according to claim 1, wherein the first etching gas comprises Cl₂ and HBr.

13. The etching method according to claim 1, wherein the first etching gas comprises Cl₂, HBr, and O₂.

14. The etching method according to claim 1,
wherein in the second etching step, a cleaning process is performed by causing a substitution reaction between Cl₂, SF₆ and CF₄ simultaneously with selective anisotropic etching.

15. An etching method, comprising:
a first etching step in which an anisotropic dry etching is performed so that a first etching amount in a silicon semiconductor region, which corresponds to 80 to 97% of a predetermined objective etching amount, is etched at a first etching rate by using a first etching gas comprising at least either hydrogen or oxygen; and
a second etching step, performed after the first etching step, in which an anisotropic dry etching is performed so that a second etching amount of the silicon semiconductor region, which corresponds to 3 to 20% of the objective etching amount, is etched at a second etching rate that is lower than the first etching rate by using a second etching gas that is free of both hydrogen and oxygen and comprises carbon and fluoride, the weight ratio of the fluorine to the carbon in the second etching gas being in a range of 6:1 to 90:1.
